(19) United States
(12) Patent Application Publication
(10) Pub. No.: US 2015/0162556 A1
(43) Pub. Date: Jun. 11, 2015

(54) PHOTOVOLTAIC DEVICE AND METHOD OF FABRICATING THEREOF

(71) Applicant: Cambridge Enterprise Limited, Cambridge (GB)

(72) Inventors: Richard Henry Friend, Cambridge (GB); Neil Clement Greenham, Cambridge (GB); Bruno Ehrler, Cambridge (GB)

(21) Appl. No.: 14/411,501

(22) PCT Filed: Jun. 28, 2013
(86) PCT No.: PCT/GB2013/051726

§ 371 Date: Dec. 27, 2014

(30) Foreign Application Priority Data
Jun. 29, 2012 (GB) 1211622.4

(51) Int. Cl. H01L 51/42; H01L 31/18

(52) U.S. Cl. CPC H01L 51/4213; H01L 31/18

(57) ABSTRACT

A photovoltaic device comprising: a first electrode, a second electrode, and disposed between the first electrode and the second electrode an organic semiconductor layer capable of multiple exciton generation and an inorganic semiconductor layer, wherein an interlayer comprising an inorganic semiconductor such as a semiconductor nanocrystal is disposed between the organic and inorganic semiconductor layers.

Silicon dominates the market of solar cells because of its abundance, mature production processes and high efficiencies. Size controllable tunability of absorption spectra has made semiconductor nanocrystals also promising materials for applications in photovoltaic structures and recent work has been directed towards their integration into traditional silicon-based solar cells. To this end, “Hybrid Photovoltaics Based on Semiconductor Nanocrystals and Amorphous Silicon”, Baoquan, Sun et al., NanoLetters, 2009, Vol. 9, No. 3, 1235-1241 describes a hybrid silicon nanocrystal solar cell providing reported external quantum efficiencies of around 7% at infrared energies and around 50% in the visible with a power conversion efficiency of up to 0.9%.

An alternative approach has been pursued by Sushobhan Avasthi et al, in “Role of Majority and Minority Carrier Barriers Silicon/Organic Hybrid Heterojunction Solar Cells”, Advanced Materials, 2011, 23, 5762-5766., in which a hybrid device uses a silicon/organic polymer interface. An organic semiconductor poly(3-hexylthiophene) (P3HT) is layered on top of silicon using solution processing to fabricate a photovoltaic cell having a reported 10.1% efficiency. In order to demonstrate a detrimental effect of a hole barrier on this type of cell, the authors fabricated a device on silicon with a 9,10-phenanthrenequinone (PQ) and pentacene heterojunction concluding that hole barriers due to non-zero offset between the silicon valence band and the organic semiconductor HOMO severely degrade device performance.

According to a first aspect of the present invention, there is provided a photovoltaic device comprising: a first electrode, a second electrode, and disposed between the first electrode and the second electrode an organic semiconductor layer capable of multiple exciton generation and an adjacent inorganic semiconductor layer, wherein an interlayer comprising an inorganic semiconductor is disposed between the adjacent organic and inorganic semiconductor layers.

In a preferred embodiment of the present invention, we demonstrate a photovoltaic device that couples silicon to pentacene, an organic semiconductor we show actually improves device performance. Without wishing to be bound by any particular theory, in a preferred embodiment a thin layer of inorganic semiconductor nanocrystals does not appear to pose a barrier to the electrons or holes and may act as a protective layer to the organic semiconductor during silicon deposition over the organic semiconductor layer. Our solar cells may reach efficiencies of 2% under one sun and very advantageous external quantum efficiencies exceeding 60%.

Preferably, the organic semiconductor layer is a polyacene such as pentacene.

Preferably, the inorganic semiconductor is deposited on the organic semiconductor. In this way, the first electrode may be an anode, the second electrode is a cathode, and wherein the organic semiconductor layer is deposited on the anode.

Preferably, the inorganic semiconductor interlayer is selected to have an electron affinity that is sufficiently large to allow electron transfer to occur onto the inorganic semiconductor from the triplet exciton formed as a result of multiple exciton generation in the organic semiconductor layer.

Preferably, the inorganic semiconductor interlayer has a bandgap of 1.1 eV, optionally between 1.1 eV and 0.7 eV. This range of bandgap can be affected by control of the size of the e.g. nanocrystals, smaller sizes producing larger bandgap. Alternatively, this interlayer may be provided by any thin-film inorganic semiconductor with a bandgap in this range. This may be provided a number of ternary and quaternary inorganic materials. For example, Copper indium gallium (di)selenide (CIGS) which is a I-III-VI₂ semiconductor material composed of copper, indium, gallium, and selenium. The material is a solid solution of copper indium selenide (often abbreviated “CIS”) and copper gallium selenide. It has a chemical formula of CuInₓGa₍₁₋ₓ₎Se₂ where the value of x can vary from 1 (pure copper indium selenide) to 0 (pure copper gallium selenide). CIGS is a tetrahedrally bonded semiconductor, with the chalcopyrite crystal structure, and a bandgap varying continuously with x from about 1.0 eV (for copper indium selenide) to about 1.7 eV (for copper gallium selenide). Perovskite structures containing, for example, lead may also provide bandgaps in this range.

Preferably, where the interlayer comprises an inorganic nanocrystal, the inorganic nanocrystal comprises lead chalcogenide nanocrystals. More preferably, the lead chalcogenide nanocrystals are lead selenide or lead sulfide.

Preferably, the nanocrystals comprise any one or more of CdSe, CdS, ZnTe, ZnSe, PbS, PbSe, PbTe, HgS, HgSe, HgTe, HgCdTe, CdTe, CZTS, ZnS, CuInS₂, CuInGaSe, CuInGaS, Si, InAs, InP, InSb, SnS₂, CuS, or Fe₂S₃.

Preferably, the inorganic semiconductor layer comprises amorphous silicon.

Preferably, the inorganic semiconductor layer comprises crystalline silicon, copper indium gallium selenide (CIGS), germanium, GaAs, CdTe or perovskite semiconductors such as organometal halide perovskite semiconductors and more specifically methylammonium lead iodide chloride (CH₃NH₃PbI₂Cl).

Preferably, the organic semiconductor layer has the structure of a porous film and the interlayer is a film disposed over and interpenetrating with the film of the organic semiconductor layer at one side of the film and at another side of the organic semiconductor film being adjacent the inorganic semiconductor layer.

Preferably, the interlayer has a thickness of 5 nm to 300 nm.

Preferably, the interlayer has a thickness of 10 nm to 30 nm, 30 nm to 70 nm, or preferably around 50 nm.

Preferably, a solar cell is provided with an array of photovoltaic devices at least one of the photovoltaic devices being a photovoltaic device according to the present invention.

According to a second aspect of the present invention, a method of fabricating a photovoltaic device comprises depositing an organic semiconductor layer capable of multiple exciton generation over a first electrode; depositing, over the organic semiconductor layer an inorganic semiconductor interlayer; and depositing an inorganic semiconductor layer over the inorganic semiconductor interlayer; and depositing a second electrode over the inorganic semiconductor layer.

Preferably, the method also includes depositing a cross-linking ligand layer over the organic semiconductor layer prior to depositing the inorganic semiconductor interlayer.

Preferably, depositing the inorganic semiconductor interlayer includes spin-coating, spray coating, inkjet printing, gravure printing, microgravure printing, slot-die coating, dip coating, spray pyrolysis, or screen printing and preferably depositing the inorganic semiconductor layer includes sputtering, optionally RF sputtering, PECVD, RF-PECVD, hydrogen-diluted RF-PECVD, hot-wire catalytic deposition, VHF Glow Discharge Deposition, Indirect Microwave Deposition.

The above device materials and method may be employed, in part at least, as part of an existing fabrication line. For example in a third aspect of the present invention a method of fabricating a photovoltaic device includes providing an inorganic semiconductor substrate e.g. comprising silicon; depositing over the inorganic semiconductor substrate an inorganic semiconductor interlayer; and depositing over the inorganic semiconductor interlayer an organic semiconductor capable of multiple exciton generation.

The photovoltaic device generates photocurrent through absorption of light in either or both of the inorganic semiconductor layer and the organic semiconductor layer. Without wishing to be bound by any particular theory, the interlayer may act as a protective layer to the organic semiconductor layer during deposition of the inorganic semiconductor layer, and/or as an interface between the organic semiconductor layer and the inorganic semiconductor layer and/or the interlayer may also absorb light and generate excited states. Advantageously, the device utilizes exciton multiplication through singlet fission to triplet exciton pairs. In this way the organic semiconductor layer e.g., pentacence, produces pairs of excitons from higher energy visible spectrum photons and the interlayer e.g. a nanocrystal layer of PbS or PbSe and the inorganic semiconductor may produce single excitons from lower energy infra-red photons to allow, in principle, for the device performance to exceed the so-called Shockley Quiesser limit.

Embodiments of the invention will now be described, by way of example only, and with reference to the following drawings of which:

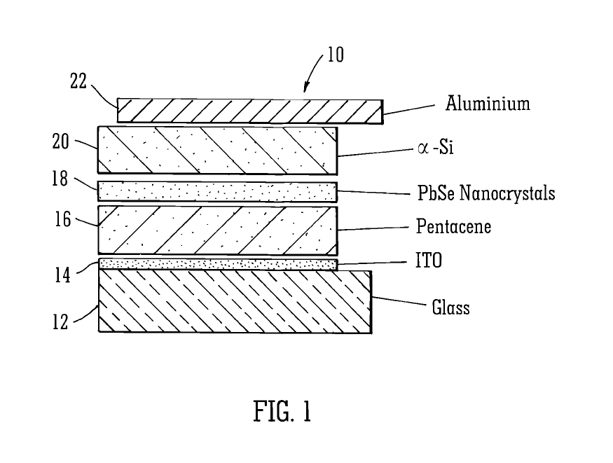

FIG. 1 is a device schematic of a photovoltaic cell according to a first embodiment of the present invention;

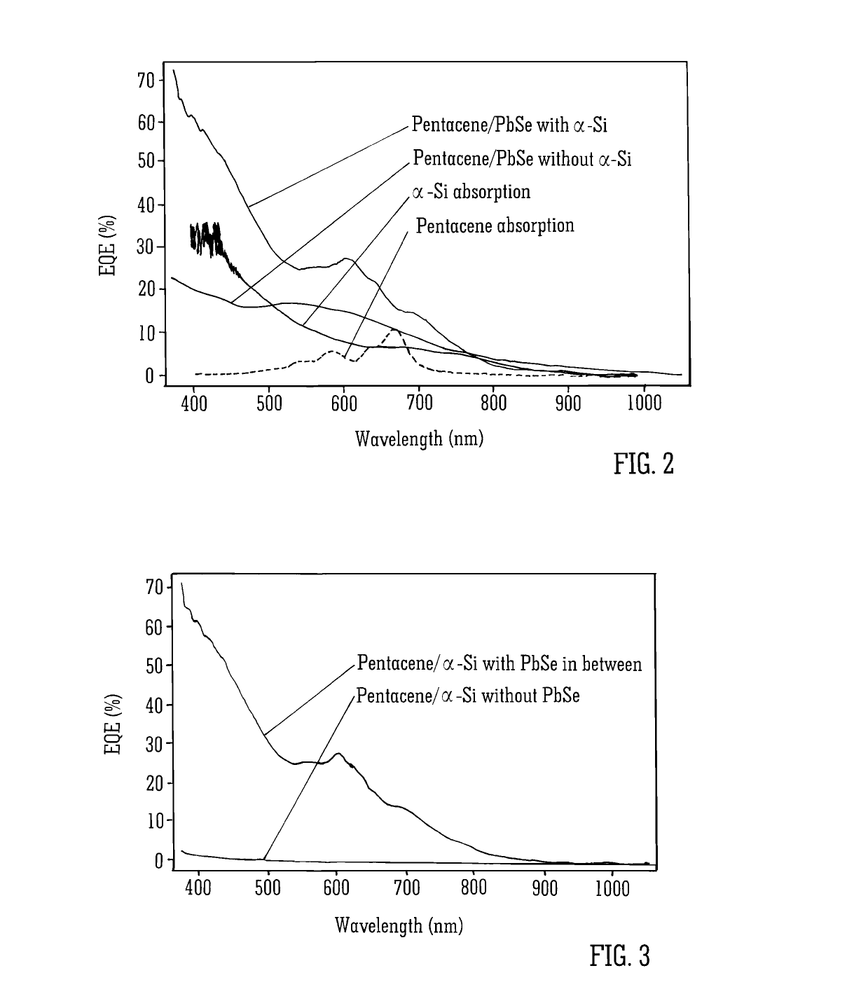

FIG. 2 is a graph showing the external quantum efficiencies of a photovoltaic cell according to the first embodiment of the present invention and a comparative device without an inorganic silicon layer, absorption spectra of silicon and pentacene are also shown;

FIG. 3 is a graph showing the external quantum efficiency of a device according to the invention and a comparative device without a nanocrystal interlayer;

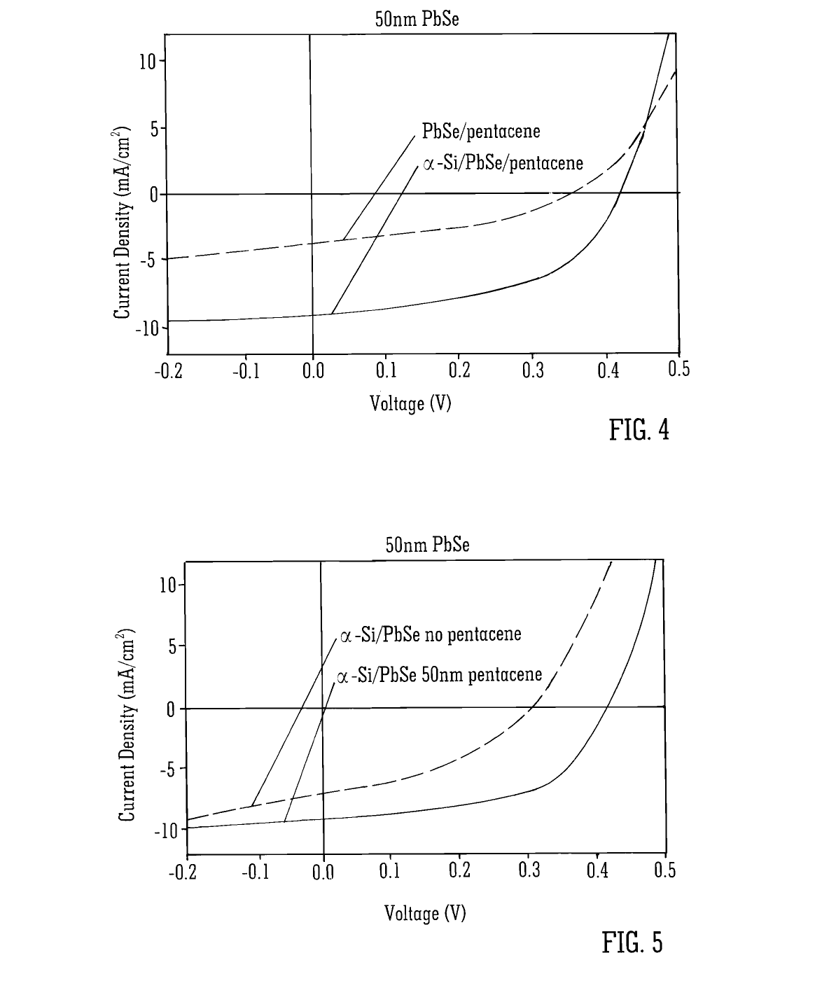

FIG. 4 is a graph showing the performance of a device according to the invention and a comparative device without silicon;

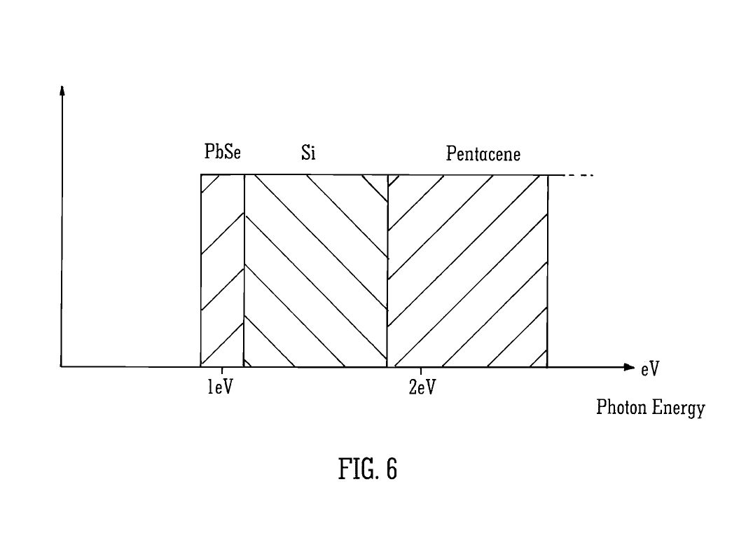

FIG. 5 is a graph showing the performance of a device according to the invention and a comparative device without pentacene;

FIG. 6 is a schematic diagram of a use of an interlayer as a light absorber according to a second embodiment of the present invention; and

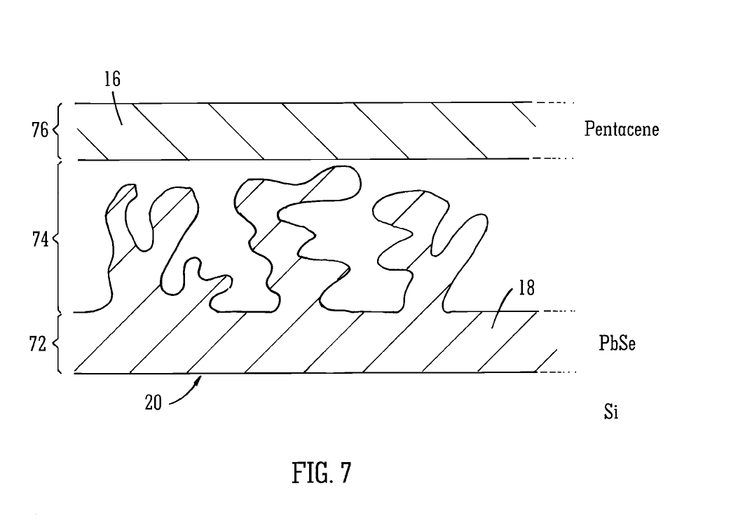

FIG. 7 is a schematic representation of an organic semiconductor layer and an interlayer of an embodiment of the present invention.

In a first embodiment of the invention, trilayer solar cells are produced by evaporating pentacene on ITO/glass substrates, followed by spin-coating of the nanocrystals with a layer-by-layer technique crosslinked with 1,3-benzenedithiol. Silicon is then sputtered on top of the nanocrystal layer followed by thermal evaporation of the top electrode.

Thus, FIG. 1 illustrates a trilayer solar cell or photovoltaic device 10 comprising a glass substrate 12 bearing an indium tin oxide (ITO) patterned anode upon which an organic semiconductor layer 16 of pentacene is deposited. An inorganic semiconductor interlayer 18 of PbSe nanocrystals is deposited on the organic semiconductor layer 16 and an inorganic semiconductor layer 20 of amorphous silicon is deposited on the inorganic semiconductor interlayer 18. A cathode 22 comprising aluminium is deposited on the inorganic semiconductor layer 20.

### Results

FIG. 2 shows the external quantum efficiency of the trilayer solar cells in comparison to a solar cell that does not contain silicon. The absorption spectra of pentacene and α-Si are also shown. The EQE of the solar cell that contains silicon clearly resembles features of all three, pentacene, nanocrystals and silicon. The solar cell that lacks silicon produces significantly less photocurrent in the spectral region where the silicon absorbs. This also indicates that both active materials contribute to the photocurrent. It implies further that the triplets from pentacene were successfully harvested and the electrons transferred to the silicon.

FIG. 3 shows the EQE spectra of a solar cell that did not have the nanocrystal interlayer. The photocurrent is close to zero over the entire range of incident light energy, without wishing to be bound by any particular theory, this appears to indicate that the solar cell was harmed during the sputtering process and/or that an interlayer provides an essential interface.

FIG. 4 shows the current-voltage behavior under one sun illumination (AM 1.5 G) comparing a device with silicon to one without the silicon layer and FIG. 5 shows one that does not have a pentacene layer. Both the silicon and the pentacene increase the photocurrent, again consistent with photocurrent generation from both. Without wishing to be bound by any particular theory, the strong increase in photovoltage upon insertion of the pentacene layer is probably due to the good hole extraction properties of pentacene.

With reference to FIG. 6, a schematic diagram of a use of an interlayer as a light absorber according to a second embodiment of the present invention illustrates a nanocrystal PbSe selected to absorb at a photon energy of around 1 eV. When combined with a device of the first embodiment, the interlayer may also act as a light absorber.

FIG. 7 shows an organic semiconductor layer 16 having the structure of a porous film and an interlayer 18 disposed over and interpenetrating with the film of the organic semiconductor 16. The region 76 is substantially pure organic semiconductor. The region 72 is substantially pure inorganic interlayer. The region 74 is a region of interpenetration between the organic semiconductor and the inorganic interlayer.

### EXPERIMENTAL

PbSe Nanocrystal Synthesis

PbSe nanocrystals were synthesized as known in the art and in a three-neck flask, lead oleate (Pb(OAc)2H2O, 3.44 mmol; 1.3 g) was degassed in a mixture of 1-octadecene (ODE; 75 mmol; 24 ml) and oleic acid (OA; 8.58 mmol; 2.7 ml) for 90 minutes at 70° C. under vacuum (10-2 mbar or better). The reaction mixture was then put under nitrogen atmosphere and the temperature was increased to 160° C. to complex the lead oleate, leaving a clear, colorless solution. A second precurser solution was prepared from selenium (Alfa Aeser, 10.8 mmol; 852.8 mg) and diphenylphosphine (DPP; 15 μmol; 26.1 μl) in tri-n-octylphosphine (TOP; 24.2 mmol; 10.8 ml) and stirred in a glovebox at 70° C. until the selenium was dissolved. The selenium precursor was rapidly injected into the flask at 100-120 ° C. and the nanocrystals were grown for 1-5 minutes. Cooling the reaction flask using room temperature water swiftly stopped the reaction. The nanocrystals were purified three times using 1-butanol and methanol in a nitrogen filled glovebox.

Device Fabrication

Trilayer solar cells were prepared on pre-patterned ITO substrates that were cleaned by subsequent sonification in acetone and isopropanol for 10 minutes. They were then treated with oxygen plasma for 10 minutes to remove residual organics. Pentacene was evaporated where applicable in a thermal evaporator (Kurt J. Lesker) at a pressure below 10-6 mbar. The rate was kept at or below 0.1 Å/s. PbSe nanocrystal films were deposited using a layer-by-layer technique.

The spin coater was set to spin for 10 s at 1500 rpm after a 3 s wait. First a layer of 1,3-benzenedithiol in acetonitrile (BDT, 0.02M) was spun followed by washing with pure acetonitrile. Then a thin layer PbSe nanocrystals (12-25 mg/mL in octane) capped with oleic acid ligands was deposited and crosslinked with BDT followed by washing with acetonitrile and octane. This cycle was repeated until the desired thickness was achieved. Amorphous silicon was sputtered using a DC magnetron sputtering system operated at 330V with Ar as the sputtering gas (approximately 1.0 Pa). The sputtering rate was 20 nm/min. The chamber was cooled with liquid nitrogen to prevent heating of the substrates during sputtering and to improve the vacuum (base pressure<10⁻¹² mbar). The amorphous nature of silicon was confirmed using XRD.

The samples were returned to nitrogen atmosphere within 5 minutes and transferred into a thermal evaporator for deposition of the top contact. Lithium fluoride and aluminum were evaporated at a rate of 0.05-0.5 nm/s. The devices were than encapsulated by gluing a glass slide on the top using a transparent epoxy and measured in ambient atmosphere.

Solar Cell Measurement

External quantum efficiencies were measured with light passing through an Oriel Cornerstone 260 monochromator. The current was measured under short circuit. IV-curves were recorded under 1 sun illumination from an Oriel 92250A solar simulator using a Keithley 2636A source measure unit. The illumination was corrected for spectral mismatch in the wavelength region from 375 nm to 1045 nm.

Although the embodiments above have been described in considerable detail, numerous variations and modifications will become apparent to those skilled in the art once the above disclosure is fully appreciated. It is intended that the following claims be interpreted to embrace all such variations and modifications.

1. A photovoltaic device comprising: a first electrode, a second electrode, and disposed between the first electrode and the second electrode an organic semiconductor layer capable of multiple exciton generation and an inorganic semiconductor layer, wherein an interlayer comprising an inorganic semiconductor is disposed between the organic and inorganic semiconductor layers.

2. A photovoltaic device as claimed in claim 1, wherein the interlayer comprises a nanocrystal semiconductor.

3. A photovoltaic device as claimed in claim 1, wherein the interlayer comprises copper indium gallium selenide (CIGS), germanium or perovskite structure semiconductor compositions.

4. A photovoltaic device as claimed in claim 1, wherein the organic semiconductor layer is a polyacene.

5. A photovoltaic device as claimed in claim 4, wherein the polyacene is pentacene.

6. A photovoltaic device as claimed in claim 1, wherein the first electrode is an anode, the second electrode is a cathode, and wherein the organic semiconductor layer is deposited on the anode.

7. A photovoltaic device as claimed in claim 1, wherein the interlayer is selected to have an electron affinity that is sufficiently large to allow electron transfer to occur onto the interlayer inorganic semiconductor from a triplet exciton formed as a result from the multiple exciton generation in the organic semiconductor layer.

8. (canceled)

9. A photovoltaic device as claimed in claim 1, wherein the interlayer comprises a bulk inorganic semiconductor.

10. A photovoltaic device as claimed in claim 1, wherein the interlayer comprises lead chalcogenide nanocrystals.

11. (canceled)

12. A photovoltaic device as claimed in claim 10, wherein the lead chalcogenide nanocrystals comprise any one or more of CdSe, CdS, ZnTe, ZnSe, PbS, PbSe, PbTe, HgS, HgSe, HgTe, HgCdTe, CdTe, CZTS, ZnS, CuInS₂, CuInGaSe, CuInGaS, Si, InAs, InP, InSb, SnS₂, CuS, or Fe₂S₃.

13. A photovoltaic device as claimed in claim 1, wherein the inorganic semiconductor layer comprises amorphous silicon.

14. A photovoltaic device as claimed in claim 1, wherein the inorganic semiconductor layer comprises crystalline silicon, copper indium gallium selenide (CIGS), germanium, CdTe, GaAs or perovskite semiconductors such as organometal halide perovskite semiconductors and more specifically methylammonium lead iodide chloride (CH₃NH₃PbI₂Cl).

15. A photovoltaic device as claimed in claim 1, wherein the organic semiconductor layer has a structure of a porous film and the interlayer is a film disposed over and interpenetrating with the film of the organic semiconductor layer at one side of the film and at another side of the film being adjacent the inorganic semiconductor layer.

16. A photovoltaic device as claimed in claim 1, wherein the interlayer has a thickness of 5 nm to 300 nm.

17-18. (canceled)

19. A method of fabricating a photovoltaic device, the method comprising:
depositing an organic semiconductor layer capable of multiple exciton generation over a first electrode;
depositing, over the organic semiconductor layer an inorganic semiconductor interlayer; and
depositing an inorganic semiconductor layer over the inorganic semiconductor interlayer; and depositing a second electrode over the inorganic semiconductor layer.

20. A method as claimed in claim 19, including depositing a cross-linking ligand layer over the organic semiconductor layer prior to depositing the inorganic semiconductor interlayer.

21. A method as claimed in claim 19, wherein the depositing the inorganic semiconductor interlayer includes spin-coating, spray coating, inkjet printing, gravure printing, microgravure printing, slot-die coating, dip coating, spray pyrolysis, or screen printing.

22-24. (canceled)

25. A method as claimed in claim 20, wherein the cross-linking ligand layer comprises benzenedithiol.

26. (canceled)

27. A method as claimed in claim 19, wherein the interlayer comprises copper indium gallium selenide (CIGS), germanium or perovskite structure semiconductor compositions.

28-29. (canceled)

30. A method of fabricating a photovoltaic device, the method comprising:
providing an inorganic semiconductor substrate e.g. comprising silicon;
depositing over the inorganic semiconductor substrate an inorganic semiconductor interlayer;
and depositing over the inorganic semiconductor interlayer an organic semiconductor capable of multiple exciton generation.

31-32. (canceled)
